(19) United States
(12) Patent Application Publication
(10) Pub. No.: US 2026/0032904 A1
(43) Pub. Date: Jan. 29, 2026

(54) SEMICONDUCTOR MEMORY DEVICE AND METHOD FOR FABRICATING THE SAME

(71) Applicant: SK hynix Inc., Gyeonggi-do (KR)

(72) Inventors: Sungwon LIM, San Jose, CA (US); Tong ZHANG, San Jose, CA (US); Agus TJANDRA, San Jose, CA (US)

(21) Appl. No.: 18/783,293

(22) Filed: Jul. 24, 2024

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

A semiconductor memory device including a structure of multiple cells and a method of fabricating multiple cells. The semiconductor memory device includes a structure of multiple cells structure by cutting or separating a storage layer using a sacrificial blocking layer in oval, triangular, quadruple, and more shapes. When the storage layer is separated, each cell can act as an independent cell. The semiconductor memory device can overcome the limitations of vertical scaling in current 3D NAND memory device.

### BACKGROUND

### 1. Technical Field The present disclosure relates to a semiconductor memory device, and more particularly to a three-dimensional semiconductor memory device.

### 2. Related Art

Semiconductor memory devices may include a plurality of memory cells capable of storing data. In order to improve a degree of integration of semiconductor memory devices, three-dimensional (3D) memory devices in which memory cells are arranged in three-dimensions on a substrate have been proposed.

In this context, embodiments of the present disclosure arise.

### SUMMARY

Embodiments of the present disclosure are directed to a semiconductor memory device including multiple cells and a method for fabricating the semiconductor memory device.

In accordance with one embodiment of the present disclosure, there is provided a semiconductor memory device. The semiconductor memory device includes a pillar structure including a core hole and multiple pillar patterns surrounding the core hole and separated by the core hole, each pillar pattern including a stack of insulating and conductive layers alternatively stacked along a first direction; a storage structure formed on an inner surface of each pillar pattern in a second direction perpendicular to the first direction; a channel layer formed on an inner surface of the storage structure; and a core insulating layer formed on an inner surface of the channel layer. The inner surface of each pillar pattern includes a center area and corner areas adjacent to the center area. The storage structure includes: a blocking insulating layer formed on an inner surface of each pillar pattern; a data storage layer consisting of separation storage patterns formed on an inner surface of the blocking insulating layer at the corner areas; and a tunnel insulting layer formed on an inner surface of the blocking insulating layer at the center area and the data storage layer at the corner areas.

In accordance with another embodiment of the present disclosure, there is provided a method for manufacturing a semiconductor memory device. The method includes forming a pillar structure including a core hole and multiple pillar patterns surrounding the core hole and separated by the core hole, each pillar pattern including a stack of insulating and conductive layers alternatively stacked along a first direction; forming a storage structure on an inner surface of each pillar pattern in a second direction perpendicular to the first direction, the inner surface of each pillar pattern including a center area and corner areas adjacent to the center area; forming a channel layer on an inner surface of the storage structure; and forming a core insulating layer on an inner surface of the channel layer.

### BRIEF DESCRIPTION OF THE DRAWINGS

FIG. 1 is a block diagram illustrating a semiconductor memory device in accordance with one embodiment of the present disclosure.

FIG. 2 is a schematic circuit diagram illustrating a memory block of a semiconductor memory device in accordance with another embodiment of the present disclosure.

FIGS. 3A and 3B are views illustrating a structure of a semiconductor memory device in accordance with other embodiments of the present disclosure.

FIGS. 4A to 4E are schematic diagrams of multi-site cell structures of a semiconductor memory device in accordance with different embodiments of the present disclosure.

FIGS. 5A to 5F are views illustrating a method for fabricating a semiconductor memory device including a multi-site cell structure in accordance with embodiments of the present disclosure.

FIGS. 6A to 6F and FIGS. 7A to 7F are cross-sectional views illustrating a semiconductor memory device including a multi-site cell structure in accordance with embodiments of the present disclosure.

FIG. 8 is a flowchart illustrating a method for fabricating a multi-site cell structure in accordance with embodiments of the present disclosure.

### DETAILED DESCRIPTION

The specific structural or functional descriptions disclosed herein are merely illustrative for the purpose of describing embodiments according to the concept of the present disclosure. The embodiments according to the present disclosure can be implemented in various forms, and should not be construed as limited to the embodiments set forth herein.

Embodiments of the present disclosure provide a semiconductor memory device capable of improving a degree of integration of memory cells.

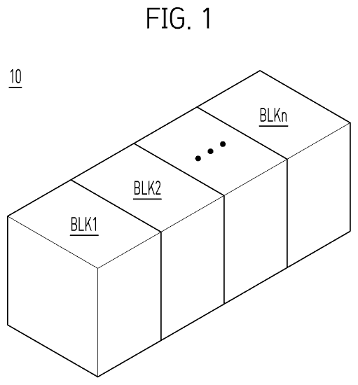

FIG. 1 is a block diagram illustrating a semiconductor memory device 10 in accordance with an embodiment of the present disclosure.

Referring to FIG. 1, the semiconductor memory device 10 may include a plurality of memory blocks BLK1 to BLKn. The semiconductor memory device 10 may be a nonvolatile memory device such as a three-dimensional (3D) nonvolatile memory device or a two-dimensional (2D) nonvolatile memory device. In some embodiments, the nonvolatile memory device may be a NAND flash memory device.

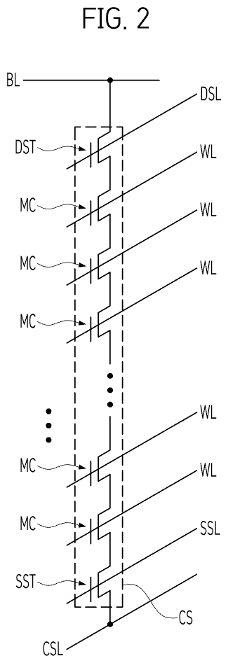

FIG. 2 is a schematic circuit diagram illustrating a memory block of a semiconductor memory device in accordance with one embodiment of the present disclosure.

Referring to FIG. 2, the memory block of the semiconductor memory device may include a memory cell string CS coupled to a bit line BL and a common source line CSL. Although a single memory cell string CS is illustrated, a plurality of memory cell strings may be coupled in parallel between the bit line BL and the common source line CSL.

The memory cell string CS may include a source select transistor SST, a plurality of memory cells MC, and a drain select transistor DST disposed between the common source line CSL and the bit line BL.

The source select transistor SST may control the electrical coupling between the plurality of memory cells MC and the common source line CSL. A single source select transistor SST may be disposed between the common source line CSL and the plurality of memory cells MC. Two or more source select transistors coupled in series to each other may be disposed between the common source line CSL and the plurality of memory cells MC. The source select transistor SST may be coupled to a source select line SSL. The operation of the source select transistor SST may be controlled by a source gate signal applied to the source select line SSL.

The plurality of memory cells MC may be disposed between the source select transistor SST and the drain select transistor DST. The memory cells MC between the source select transistor SST and the drain select transistor DST may be coupled in series to each other. The memory cells MC may be coupled to respective word lines WL. The operation of the memory cells MC may be controlled by cell gate signals applied to the word lines WL.

The drain select transistor DST may control the electrical coupling between the plurality of memory cells MC and the bit line BL. The drain select transistor DST may be coupled to a drain select line DSL. The operation of the drain select transistor DST may be controlled by a drain gate signal applied to the drain select line DSL.

Each of the memory cells MC may store single-bit data or multi-bit data.

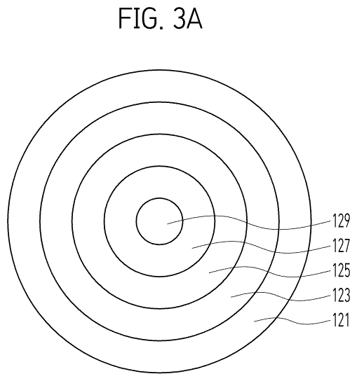

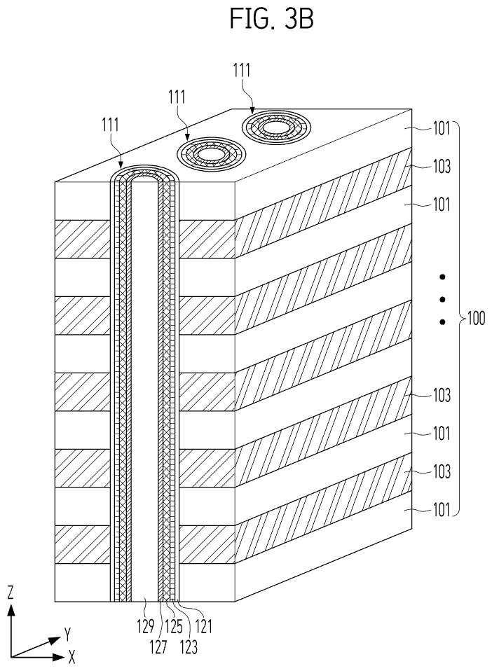

FIGS. 3A and 3B are views illustrating a structure of a semiconductor memory device in accordance with another embodiment of the present disclosure. FIG. 3A is a top view illustrating a memory cell of a semiconductor memory device, and FIG. 3B is a perspective view illustrating a semiconductor memory device (e.g., a 3D NAND flash memory device).

Referring to FIG. 3A and FIG. 3B, the semiconductor memory device may include a stacked body 100, a channel layer 127, a tunnel insulating layer 125, a data storage layer 123, and a blocking insulating layer 121.

The stacked body 100 may include interlayer insulating layers 101 and word lines 103. Each of the interlayer insulating layers 101 and the word lines 103 may be parallel to an X-Y plane. The interlayer insulating layers 101 and the word lines 103 may be stacked in a Z-axis direction perpendicular to the X-Y plane. The interlayer insulating layers 101 may be disposed alternately with the word lines 103.

The word lines 103 may be insulated from each other by the interlayer insulating layers 101. The word lines 103 may be used as the gate electrodes of the memory cells MC described with reference to FIG. 2. The interlayer insulating layers 101 may include an oxide layer (e.g., a silicon oxide layer). The word lines 103 may be initially a nitride layer (e.g., a metal nitride), but may be replaced by a doped semiconductor, metal, a metal nitride, and a metal silicide.

The stacked body 100 may be penetrated by a hole 111 extending in the Z-axis direction. The sidewalls of the interlayer insulating layers 101 may be defined along the sidewall of the hole 111. The sidewalls of the word lines 103 may be defined along the sidewall of the hole 111.

The channel layer 127 may include a semiconductor, such as silicon or the like. The channel layer 127 may extend in the Z-axis direction. The channel layer 127 may form the channel area of the memory cell string CS illustrated in FIG. 2. The channel layer 127 may be enclosed by the interlayer insulating layers 101 and the word lines 103.

The blocking insulating layer 121 may be interposed between the channel layer 127 and the stacked body 100. The blocking insulating layer 121 may include a single layer or a plurality of layers.

The data storage layer 123 may be interposed between the blocking insulating layer 121 and the channel layer 127. The data storage layer 123 may include a charge trap layer or a floating gate layer.

The tunnel insulating layer 125 may be interposed between the data storage layer 123 and the channel layer 127. The tunnel insulating layer 125 may include metal organic frameworks (MOF).

The semiconductor memory device may further include a core insulating layer 129 that fills the central area of the hole 111. The channel layer 127 may enclose the sidewall of the core insulating layer 129.

The channel layer 127, the tunnel insulating layer 125, the data storage layer 123, and the blocking insulating layer 121 may be formed in various structures.

In the illustrated example of FIG. 3B, the blocking insulating layer 121, the data storage layer 123, and the tunnel insulating layer 125 may extend in the Z-axis direction along the sidewall of the channel layer 127. Each of the blocking insulating layer 121, the data storage layer 123, and the tunnel insulating layer 125 may be disposed between each of the word lines 103 and the channel layer 127, and may extend into space between each of the interlayer insulating layers 101 and the channel layer 127.

The blocking insulating layer 121 may include a silicon oxide layer, but embodiments of the present disclosure are not limited thereto. In one embodiment, the blocking insulating layer 121 may include a silicon oxide layer and a metal oxide layer between the silicon oxide layer and the stacked body 100. The metal oxide layer may include an oxide having higher dielectric constant than that of the silicon oxide layer. In another embodiment, the metal oxide layer may include an aluminum oxide layer.

The data storage layer 123 may include a charge trap layer extending in the Z-axis direction along the sidewall of the channel layer 127. In one embodiment, the charge trap layer may include a silicon nitride layer.

To increase the integration in 3D NAND memory device, various scaling schemes have been developed. For example, the scaling schemes include a logical scaling (e.g., a single-level cell (SLC), a multi-level cell (MLC), a triple-level cell (TLC), a quad-level cell (QLC), a penta-level cell (PLC)), a vertical scaling (e.g., 100 stacks (tiers), 200 stacks, 300 stacks, 400 stacks), a lateral scaling (e.g., 3 rows between a slit to a slit as one block, 9 rows, 19 rows, in which higher rows mean higher density), and a structural scaling (e.g., 4 dimension (4D), Peri. under Cell Array (PUA), Hybrid Wafer Bonding (HWB)).

However, these schemes reach their limits in terms of physical and cost. To overcome the limitations, additional physical scaling methods are being developed through the formation of multiple cells. For example, schemes of fabricating multiple cells based on the cutting of channel area are under consideration. For example, one cutting scheme of the channel area is described in U.S. Pat. No. 12,010,844B2 issued on Jun. 11, 2024, entitled “Semiconductor device and method of manufacturing the semiconductor device”, the entire contents of which are incorporated herein by reference. Since these schemes are based on the cutting of the channel area, sufficient channel area may not be provided. Accordingly, embodiments of the present disclosure provide a structure of multiple cells (or multi-site or multi-slit cells (MSC)) and a method of fabricating multiple cells that can secure a sufficient channel area while having sufficient storage nodes.

Embodiments of the present disclosure provides a scheme of fabricating an MSC structure by cutting or separating a storage layer using a sacrificial blocking layer in oval, triangular, quadruple, and more shapes. The conventional cell structure physically forms one cell per layer on one pillar. In accordance with the embodiments of the invention, when the storage layer is separated, each cell can act as an independent cell. Therefore, the embodiments of the invention can address the limitations of vertical scaling in current 3D NAND memory device.

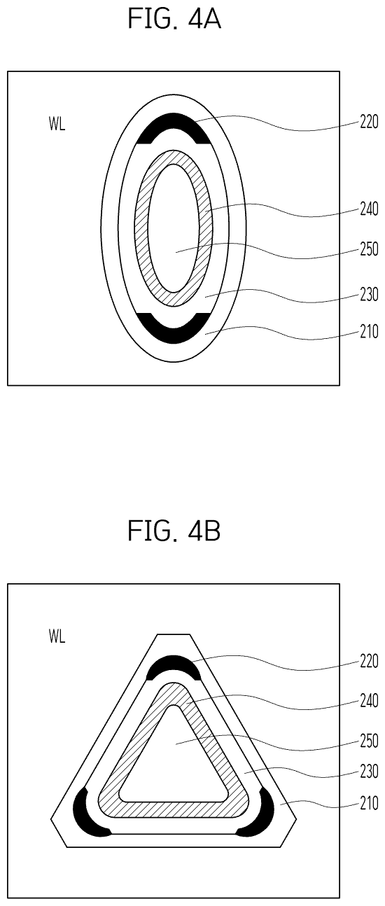

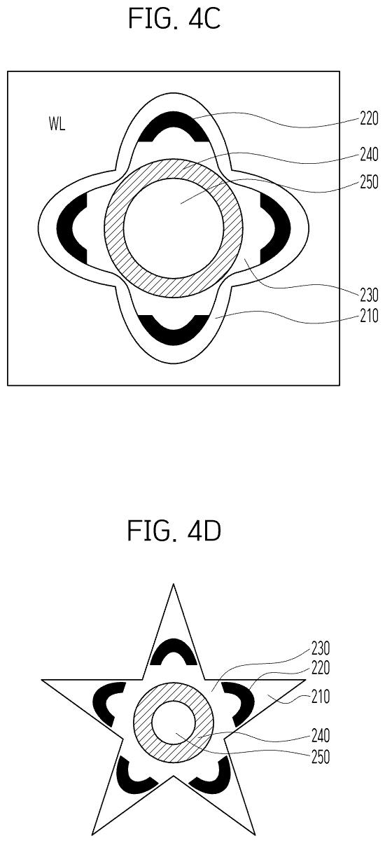

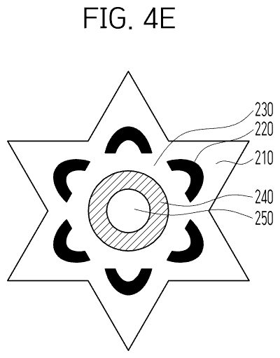

FIGS. 4A to 4E are schematic diagrams of multi-site cell structures of a semiconductor memory device in accordance with different embodiments of the present disclosure.

As shown in FIG. 4A, the multi-site cell structure may include a dual slit (or site) cell. As shown in FIG. 4B, the multi-site cell structure may include a triple slit cell. As shown in FIG. 4C, the multi-site cell structure may include a quadruple slit cell. As shown in FIG. 4D, the multi-site cell structure may include a pentagon slit cell. As shown in FIG. 4E, the multi-site cell structure may include a hexagon slit cell.

Referring to FIG. 4A, the semiconductor memory device may include a structure of a blocking insulating layer 210, a data storage layer 220, a tunnel insulating layer 230, a channel layer 240 and a core insulating layer 250. This structure may be coupled to the word lines (WL) 103 of the stacked body 100, as shown in FIGS. 3A and 3B.

The blocking insulating layer 210, the tunnel insulating layer 230, the channel layer 240 and the core insulating layer 250 corresponds to the blocking insulating layer 121, the tunnel insulating layer 123, the channel layer 127 and the core insulating layer 129, shown in FIGS. 3A and 3B, respectively.

As shown in FIG. 4A, the structure has an oval shape, and the data storage layer 220 is separated into two storage patterns. Each storage pattern can act as an independent cell. For this separation of the data storage layer 220, a sacrificial blocking layer in an oval shape which remains only over the narrow areas of the oval shape may be used to protect the data storage layer while the storage layer is being cut.

Referring to FIGS. 4B to 4E, the semiconductor memory device includes the same layers as those of FIG. 4A, but has different shapes.

As shown in FIG. 4B, the structure has a triangular shape, and the data storage layer 220 is separated as three storage patterns. Each storage pattern can act as an independent cell. For this separation of the data storage layer 220, a sacrificial blocking layer in a triangular shape may be used.

As shown in FIG. 4C, the structure has a quadruple shape, and the data storage layer 220 is separated as four storage patterns. Each storage pattern can act as an independent cell. For this separation of the data storage layer 220, a sacrificial blocking layer in a quadruple shape which remains only over the narrow areas of the quadruple shape may be used to protect the data storage layer while the storage layer is being cut.

As shown in FIG. 4D, the structure has a pentagonal shape, and the data storage layer 220 is separated as five storage patterns. Each storage pattern can act as an independent cell. For this separation of the data storage layer 220, a sacrificial blocking layer in a pentagonal shape which remains only over the narrow areas of the pentagonal shape may be used to protect the data storage layer while the storage layer is being cut.

As shown in FIG. 4E, the structure has a hexagonal shape, and the data storage layer 220 is separated as six storage patterns. Each storage pattern can act as an independent cell. For this separation of the data storage layer 220, a sacrificial blocking layer in a hexagonal shape which remains only over the narrow areas of the hexagonal shape may be used to protect the data storage layer while the storage layer is being cut.

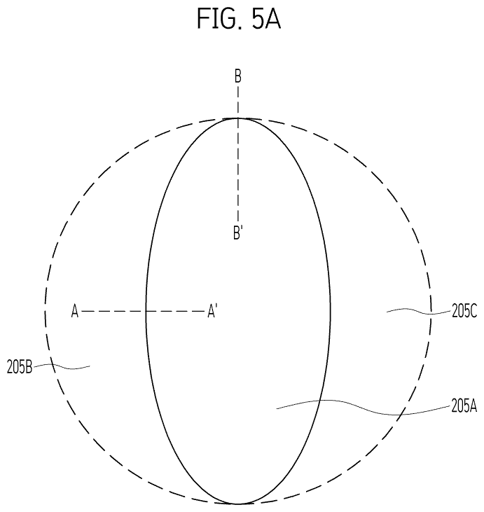

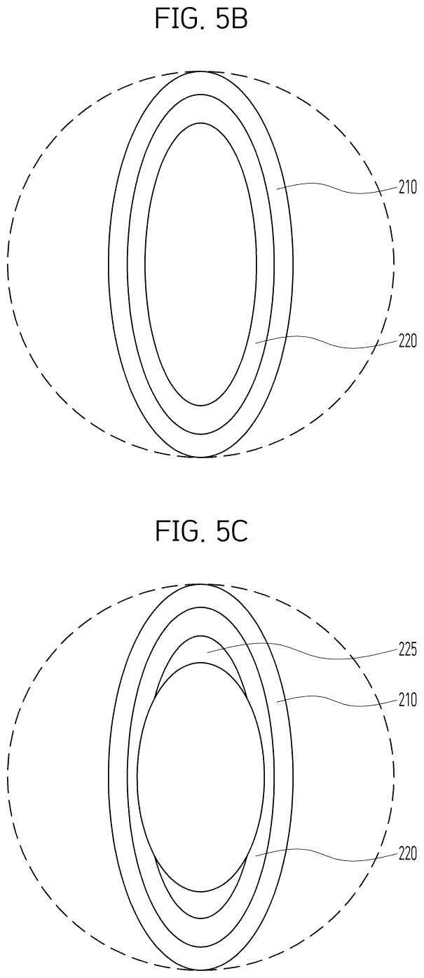

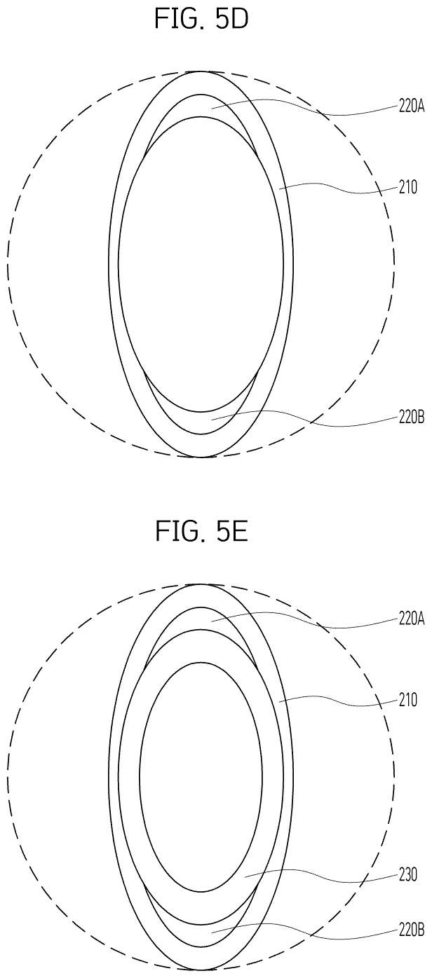

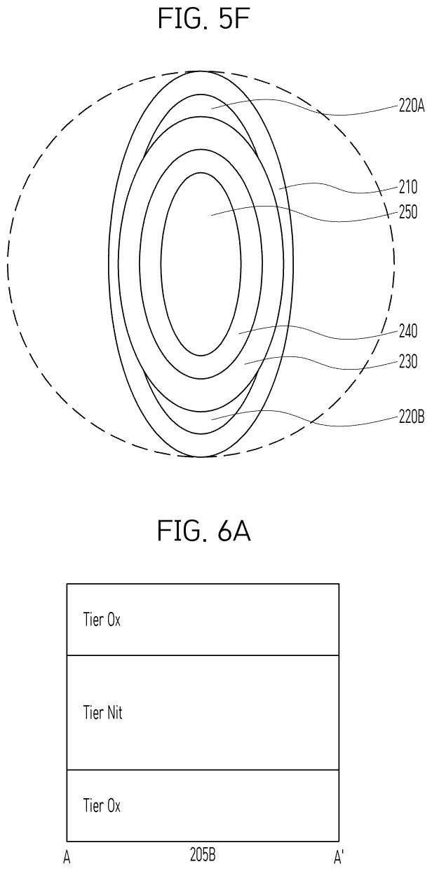

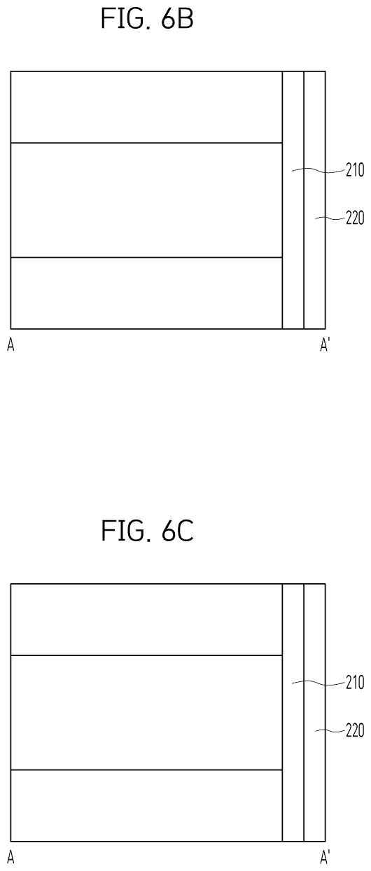

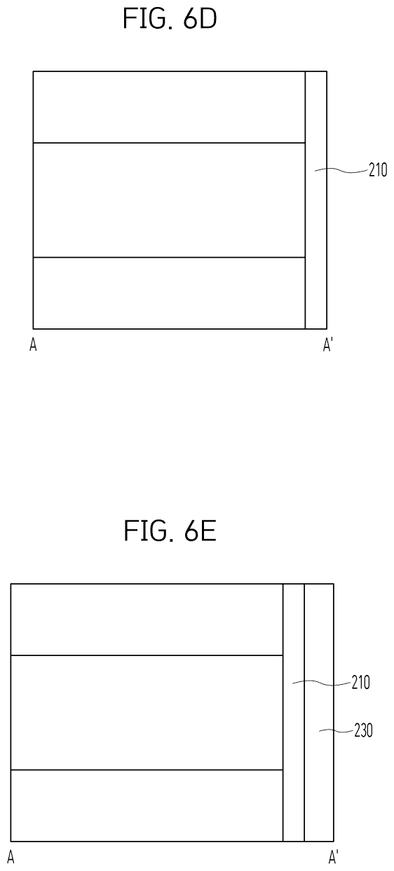

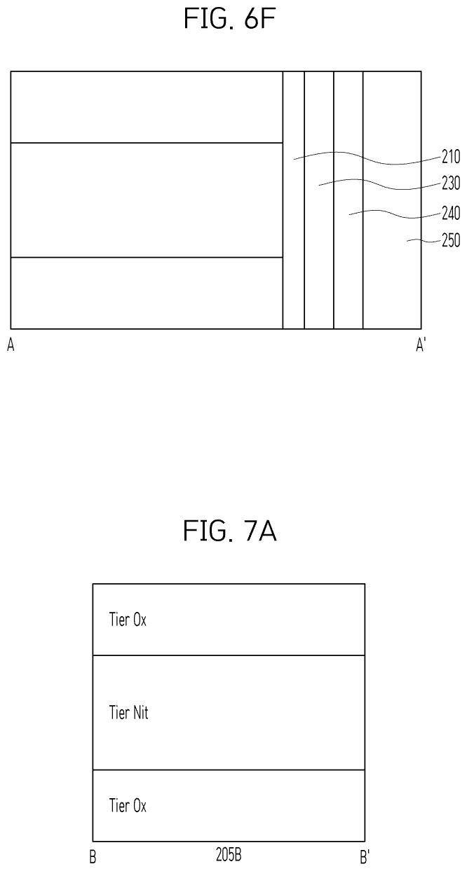

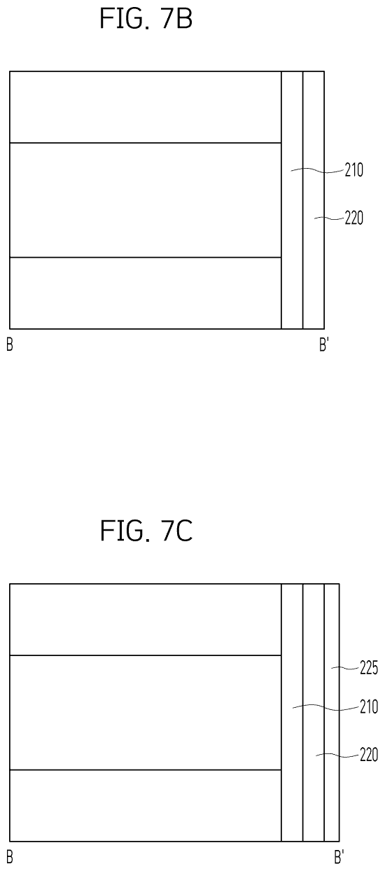

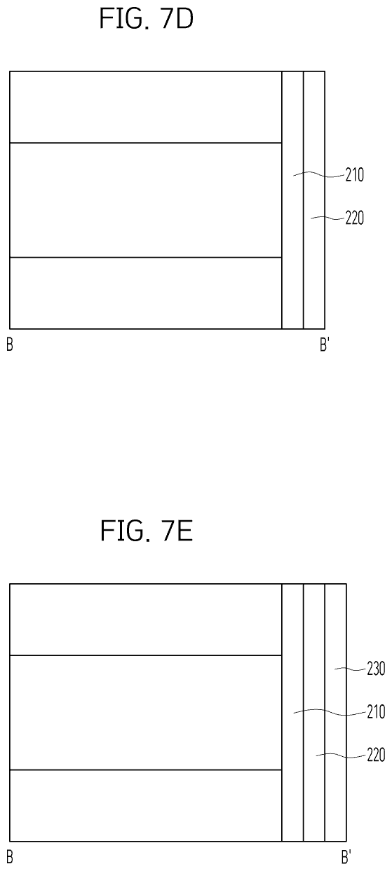

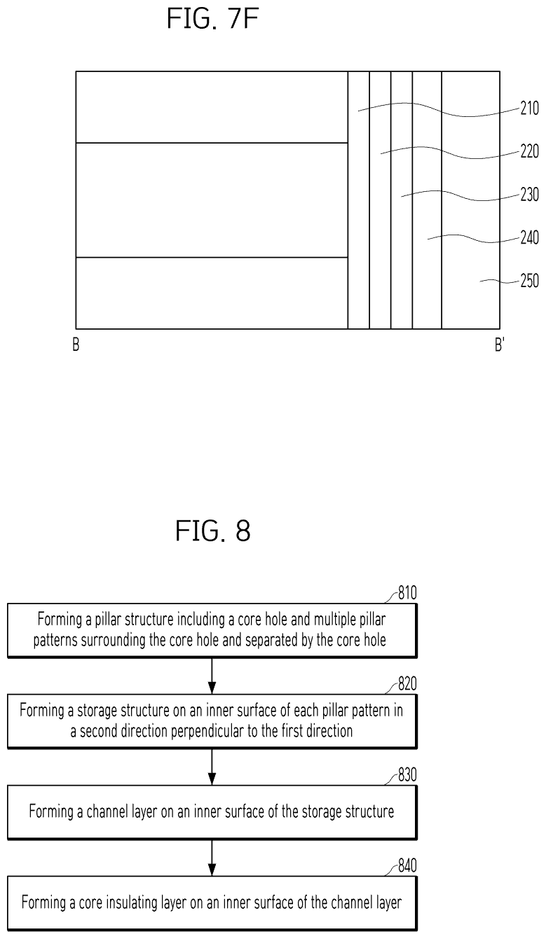

FIGS. 5A to 5F are views illustrating a method for fabricating a semiconductor memory device including a multi-site cell structure in accordance with embodiments of the present disclosure. FIGS. 6A to 6F and FIGS. 7A to 7F are cross-sectional views illustrating semiconductor memory device including a multi-site cell structure in accordance with embodiments of the present disclosure.

Referring to FIG. 5A, the semiconductor memory device may include a core hole 205A and multiple pillar patterns surrounding the core hole 205A and separated by the core hole 205A. In the illustrated example of FIG. 5A, the multiple pillar patterns may include two pillar patterns 205B, 205C. The core hole 205A may be formed by masking and etching a pillar including a stack of insulating layers 101 and conductive layers 103 alternatively stacked along a first direction (i.e., a vertical direction), as shown in FIG. 3B. That is, the resultant pillar structure may include the core hole 205A and the multiple pillar patterns 205B, 205C, and each pillar pattern may include a stack of insulating and conductive layers alternatively stacked along the first direction. In some embodiments, the stack of the insulating and conductive layers may include a structure of Oxide-Nitride-Oxide (ONO) tiers, as shown in FIGS. 7A and 7B. In some embodiments, each tier may be a stack of one oxide (insulator) and one nitride, which is replaced by metal to make metal word line.

An inner surface of each pillar pattern includes a center area, and corner areas adjacent to the center area. The center area corresponds to an area taken along a dotted line A-A′ of FIG. 5A. One of the corner areas corresponds to an area taken along a dotted line B-B′ of FIG. 5A. The other of the corner areas corresponds to an area opposite to the area taken along the line B-B′. The corner areas are areas corresponding to separation storage patterns 220A, 220B shown in FIG. 5D.

In the illustrated example of FIG. 5A, the core hole 205A has an oval shape. Alternatively, the core hole 205A may have a triangular shape, a quadruple shape, a pentagonal shape, or a hexagonal shape, as shown in FIGS. 4B to 4E.

Referring to FIGS. 5B, 6B and 7B, a blocking insulating layer 210 may be formed on an inner surface of the pillar patterns 205B, 205C. In some embodiments, the blocking insulating layer 210 may include a blocking oxide for electrical insulation from the word line (WL). The WL can be formed from one of conducting layers inside the pillar patterns 205B, 205C.

The data storage layer 220 may be deposited on an inner surface of the blocking insulating layer 210. In some embodiments, the data storage layer 220 may include a charge trap nitride that acts as a storage node. In some embodiments, the data storage layer 220 may include a single layer or multiple layers, each of which includes materials such as silicon nitride (Si3N4) and doped poly silicon (doped-poly-si).

Referring to FIGS. 5C and 7C, the data storage layer 220 may be covered by a sacrificial blocking layer 225 to remain only at the narrow areas (i.e., corner areas) in the dual, triple, quadruple, or more shapes formed through the pillar mask and etching process.

The sacrificial blocking layer 225 may have sufficient dry and wet etching selectivity with the data storage layer 220. In some embodiments, the dry and wet etching selectivity may be determined such that there is no damage or loss of the data storage layer 220, or damage or loss of the data storage layer 220 is minimized, during the separation process of the sacrificial blocking layer 225. In some embodiments, the sacrificial blocking layer 225 may include materials such as oxide, nitride, or undoped poly silicon (undoped-poly-si), taking into account the stack of the storage node (i.e., the data storage layer 220).

To separate the data storage layer 220, the sacrificial blocking layer 225 may be separated through a dry or wet etching process. In some embodiments, an isotropic etching method is used to separate each layer using the deposition characteristics of the sacrificial blocking layer 225, which has a thicker thickness in a narrow area.

Referring to FIGS. 5D, 6D and 7D, the data storage layer 220 may be selectively separated into separation storage patterns 220A, 220B through wet or dry etching using the separated blocking layer as a barrier. Each of the physically separated storage patterns 220A, 220B acts as an individual memory cell. As such, the data storage layer 220 may consist of the separation storage patterns 220A, 220B formed on an inner surface of the blocking insulating layer 210 at the corner areas.

Referring to FIGS. 5E, 6E and 7E, a tunnel insulting layer 230 may be formed on an inner surface of the blocking insulating layer 210 at the center area and the separation storage patterns of the data storage layer 220A, 220B at the corner areas. In some embodiments, the tunnel insulting layer 230 may include a material such as an oxide.

As such, the blocking insulating layer 210, the separation storage patterns 220A, 220B, and the tunnel insulting layer 230 may form a storage structure, which is formed on an inner surface of each pillar pattern in a second direction (i.e., a horizontal direction) perpendicular to the first direction.

Referring to FIGS. 5F, 6F and 7F, a channel layer 240 may be formed on an inner surface of the tunnel insulting layer 230 of the storage structure. In some embodiments, the channel layer 240 may include a material such as poly silicon (poly-si). A core insulating layer 250 may be formed on an inner surface of the channel layer 240. In some embodiments, the core insulating layer 250 may include a material such as oxide to fill the remaining hole (i.e., gap) of the core hole 205A.

As such, the channel layer 240 is deposited similarly to that of the conventional cell. That is, in the embodiments of the present disclosure, the channel layer 240 is not cut. Thus, it is possible to have sufficient channel area and thus have a higher cell string current caused by the higher channel area, compared to the MSC structure based on the channel cutting scheme.

As described above, FIGS. 5A to 7F illustrate a method for fabricating a semiconductor memory device including a multi-site cell structure including a dual site cell as shown in FIG. 4A. Although not illustrated, similar fabricating methods may be performed for the semiconductor memory device including a triple site cell shown in FIG. 4B, a quadruple site cell shown in FIG. 4C, a pentagon site cell shown in FIG. 4D, and a hexagon site cell shown in FIG. 4E.

FIG. 8 is a flowchart illustrating a method for fabricating a multi-site cell structure in accordance with embodiments of the present disclosure. As one example, FIG. 8 illustrates a method for fabricating a semiconductor memory device including a multi-site cell structure including a dual site cell based on shown in FIG. 4A.

Referring to FIG. 8, the method may include forming (810) a pillar structure including a core hole and multiple pillar patterns surrounding the core hole and separated by the core hole. In some embodiments, each pillar pattern may include a stack of insulating and conductive layers alternatively stacked along a first direction.

The method may include forming (820) a storage structure on an inner surface of each pillar pattern in a second direction perpendicular to the first direction. In some embodiments, the inner surface of each pillar pattern may include a center area and corner areas adjacent to the center area.

The method may include forming (830) a channel layer on an inner surface of the storage structure.

The method may include forming (840) a core insulating layer on an inner surface of the channel layer.

In some embodiments, the forming of the storage structure may include: forming a blocking insulating layer on an inner surface of each pillar pattern; forming a data storage layer having separation storage patterns on an inner surface of the blocking insulating layer at the corner areas; and forming a tunnel insulting layer on an inner surface of the blocking insulating layer at the center area and the data storage layer at the corner areas.

In some embodiments, the core hole has one selected shape selected from oval, triangular, and quadruple shapes. When the core hole has the oval shape, the multiple pillar patterns include two pillar patterns. When the core hole has the triangular shape, the multiple pillar patterns include three pillar patterns. When the core hole has the quadruple shape, the multiple pillar patterns include four pillar patterns.

In some embodiments, the core hole is formed by etching a stacked body of insulating and conductive layers alternatively stacked along the first direction according to the selected shape, the core hole passing through the stacked body.

In some embodiments, the forming of the separation storage patterns of the data storage layer includes: depositing, for the data storage layer, a storage center pattern at the center area and the separation storage patterns at the corner areas; depositing a sacrificial blocking layer on the inner surface of the separation storage patterns at the corner areas; and etching the storage center pattern at the center area and the sacrificial blocking layer at the corner areas.

In some embodiments, the depositing of the sacrificial blocking layer includes: depositing the sacrificial blocking layer on the data storage layer at the center area and corner areas; and etching the sacrificial blocking layer at the center area such that the sacrificial blocking layer covers the inner surface of the separation storage patterns at the corner areas.

In some embodiments, the etching of the storage center pattern at the center area and the sacrificial blocking layer at the corner areas includes an isotropic etching such that the etching of the sacrificial blocking layer at the corner areas etches a thicker thickness of the sacrificial blocking layer than the etching of the storage center pattern at the center area.

In some embodiments, the sacrificial blocking layer includes an oxide, nitride, or undoped polysilicon layer.

In some embodiments, the data storage layer includes a single layer or multiple layers.

In some embodiments, the data storage layer includes a silicon nitride or doped polysilicon layer.

Fabricating methods similar to the method shown in FIG. 8 may be performed for the semiconductor memory device including a triple slit cell shown in FIG. 4B, a quadruple slit cell shown in FIG. 4C, a pentagon slit cell shown in FIG. 4D, and a hexagon slit cell shown in FIG. 4E.

As described above, embodiments of the present disclosure provide a semiconductor memory device including multiple cells and a method for fabricating the semiconductor memory device. Embodiments of the present disclosure can secure sufficient channel area while having sufficient storage nodes.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A semiconductor memory device comprising:
a pillar structure including a core hole and multiple pillar patterns surrounding the core hole and separated by the core hole, each pillar pattern including a stack of insulating and conductive layers alternatively stacked along a first direction;
a storage structure formed on an inner surface of each pillar pattern in a second direction perpendicular to the first direction;
a channel layer formed on an inner surface of the storage structure; and
a core insulating layer formed on an inner surface of the channel layer,
wherein the inner surface of each pillar pattern includes a center area and corner areas adjacent to the center area, and
wherein the storage structure includes:
a blocking insulating layer formed on an inner surface of each pillar pattern;
a data storage layer having separation storage patterns formed on an inner surface of the blocking insulating layer at the corner areas; and
a tunnel insulting layer formed on an inner surface of the blocking insulating layer at the center area and on the data storage layer at the corner areas.

2. The semiconductor memory device of claim 1, wherein the core hole has one selected shape selected from one of oval, triangular, and quadruple shapes,
when the core hole has the oval shape, the multiple pillar patterns include two pillar patterns,
when the core hole has the triangular shape, the multiple pillar patterns include three pillar patterns, or
when the core hole has the quadruple shape, the multiple pillar patterns include four pillar patterns.

3. The semiconductor memory device of claim 2, wherein the core hole is formed by etching the stacked of insulating and conductive layers alternatively stacked along the first direction according to the selected shape, the core hole passing through the stacked body.

4. The semiconductor memory device of claim 1, wherein the separation storage patterns of the data storage layer are formed by:
depositing, for the data storage layer, a storage center pattern at the center area and the separation storage patterns at the corner areas;
depositing a sacrificial blocking layer on the inner surface of the separation storage patterns at the corner areas; and
etching the storage center pattern at the center area and the sacrificial blocking layer at the corner areas.

5. The semiconductor memory device of claim 4, wherein the sacrificial blocking layer is deposited on the inner surface of the separation storage patterns at the corner areas by:
depositing the sacrificial blocking layer on the data storage layer at the center area and corner areas; and
etching the sacrificial blocking layer at the center area such that the sacrificial blocking layer covers the inner surface of the separation storage patterns at the corner areas.

6. The semiconductor memory device of claim 5, wherein the etching of the storage center pattern at the center area and the sacrificial blocking layer at the corner areas includes an isotropic etching such that the etching of the sacrificial blocking layer at the corner areas is etching a thicker thickness of the sacrificial blocking layer at the corner areas than the etching of the storage center pattern at the center area.

7. The semiconductor memory device of claim 5, wherein the sacrificial blocking layer includes an oxide, a nitride, or an undoped polysilicon layer.

8. The semiconductor memory device of claim 1, wherein the data storage layer includes a single layer or multiple layers.

9. The semiconductor memory device of claim 8, wherein the data storage layer includes a silicon nitride or a doped polysilicon layer.

10. The semiconductor memory device of claim 1, wherein the stack includes an oxide-nitride-oxide (ONO) structure.

11. A method for manufacturing a semiconductor memory device comprising:
forming a pillar structure including a core hole and multiple pillar patterns surrounding the core hole and separated by the core hole, each pillar pattern including a stack of insulating and conductive layers alternatively stacked along a first direction;
forming a storage structure on an inner surface of each pillar pattern in a second direction perpendicular to the first direction, the inner surface of each pillar pattern including a center area and corner areas adjacent to the center area;
forming a channel layer on an inner surface of the storage structure; and
forming a core insulating layer on an inner surface of the channel layer,
wherein the forming of the storage structure includes:
forming a blocking insulating layer on an inner surface of each pillar pattern;
forming a data storage layer having separation storage patterns on an inner surface of the blocking insulating layer at the corner areas; and
forming a tunnel insulting layer on an inner surface of the blocking insulating layer at the center area and on the data storage layer at the corner areas.

12. The method of claim 11, wherein the core hole has one selected shape of oval, triangular, and quadruple shapes,
when the core hole has the oval shape, the multiple pillar patterns include two pillar patterns,
when the core hole has the triangular shape, the multiple pillar patterns include three pillar patterns, or
when the core hole has the quadruple shape, the multiple pillar patterns include four pillar patterns.

13. The method of claim 12, wherein the core hole is formed by etching the stack of insulating and conductive layers alternatively stacked along the first direction according to the selected shape, the core hole passing through the stacked body.

14. The method of claim 11, wherein the forming of the separation storage patterns of the data storage layer includes:
depositing, for the data storage layer, a storage center pattern at the center area and the separation storage patterns at the corner areas;
depositing a sacrificial blocking layer on the inner surface of the separation storage patterns at the corner areas; and
etching the storage center pattern at the center area and the sacrificial blocking layer at the corner areas.

15. The method of claim 14, wherein the depositing of the sacrificial blocking layer includes:
depositing the sacrificial blocking layer on the data storage layer at the center area and corner areas; and
etching the sacrificial blocking layer at the center area such that the sacrificial blocking layer covers the inner surface of the separation storage patterns at the corner areas.

16. The method of claim 15, wherein the etching of the storage center pattern at the center area and the sacrificial blocking layer at the corner areas includes an isotropic etching such that the etching of the sacrificial blocking layer at the corner areas is etching a thicker thickness of the sacrificial blocking layer at the corner areas than the etching of the storage center pattern at the center area.

17. The method of claim 15, wherein the sacrificial blocking layer includes an oxide, nitride, or undoped polysilicon layer.

18. The method of claim 11, wherein the data storage layer includes a single layer or multiple layers.

19. The method of claim 18, wherein the data storage layer includes a silicon nitride or a doped polysilicon layer.

20. The method of claim 11, wherein the stack includes an oxide-nitride-oxide (ONO) structure.
